(19) United States
(12) Patent Application Publication
(10) Pub. No.: US 2025/0022828 A1
(43) Pub. Date: Jan. 16, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Hyoeun Kim, Suwon-si (KR); Haksun Lee, Suwon-si (KR); Dohyun Kim, Suwon-si (KR); Sunkyoung Seo, Suwon-si (KR); Chajea Jo, Suwon-si (KR)

(21) Appl. No.: 18/609,921

(22) Filed: Mar. 19, 2024

(30) Foreign Application Priority Data
Jul. 11, 2023 (KR) 10-2023-0089808

(51) Int. Cl. H01L 23/00; H01L 25/18; H10B 80/00

(52) U.S. Cl. CPC H01L 24/29; H01L 24/08; H01L 24/32; H01L 24/96; H01L 25/18; H01L 24/13; H01L 2224/08237; H01L 2224/13023; H01L 2224/29187; H01L 2224/32227; H01L 2224/96; H01L 2924/1431; H10B 80/00

(57) ABSTRACT

The present disclosure relates to semiconductor packages and methods of fabricating the semiconductor packages. An example semiconductor package includes a first semiconductor die including a first substrate and a first bonding layer on the first substrate, a second semiconductor die disposed on the first semiconductor die, the second semiconductor die including a second substrate and a second bonding layer under the second substrate, and a silicon oxide layer interposed between the first semiconductor die and the second semiconductor die, where at least one pore is disposed in the silicon oxide layer, and the at least one pore has a height of 1 Å to 2 nm.

### CROSS-REFERENCE TO RELATED APPLICATION

This application claims priority under 35 U.S.C. § 119 to Korean Patent Application No.10-2023-0089808, filed on Jul. 11, 2023, in the Korean Intellectual Property Office, the entire contents of which are hereby incorporated by reference.

### BACKGROUND

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. Various researches for improving reliability and miniaturization of semiconductor packages have been conducted with the development of an electronic industry.

### SUMMARY

The present disclosure relates to semiconductor packages, including a semiconductor package with improved reliability, as well as methods of fabricating semiconductor packages including a method of fabricating a semiconductor package capable of improving yield.

The problem to be solved by the scope of the technology described herein is not limited to the problems mentioned above, and other problems not mentioned will be clearly understood by those skilled in the art from the description below.

In some implementations, a semiconductor package includes a first semiconductor die including a first substrate and a first bonding layer on the first substrate, a second semiconductor die disposed on the first semiconductor die, including a second substrate and a second bonding layer under the second substrate, and a silicon oxide layer interposed between the first semiconductor die and the second semiconductor die, wherein at least one pore is disposed in the silicon oxide layer, and the pore has a height of 1 Å to 2 nm.

In some implementations, a semiconductor package includes a first semiconductor die including a first substrate and a first bonding layer on the first substrate, a second semiconductor die disposed on the first semiconductor die, including a second substrate and a second bonding layer under the second substrate, and a silicon oxide layer interposed between the first semiconductor die and the second semiconductor die, wherein at least one pore is disposed in the silicon oxide layer, the first bonding layer and the second bonding layer include a plurality of SiCN grains, and a height of the pore is smaller than an average size of the SiCN grains.

In some implementations, a semiconductor package includes a first semiconductor die including a first substrate, a first bonding layer on the first substrate, and a first conductive pattern passing through the first bonding layer, a second semiconductor die disposed on the first semiconductor die and partially exposing an upper surface of the first semiconductor die, including a second substrate, a second bonding layer under the second substrate, and a second conductive pattern penetrating the second bonding layer, a silicon oxide layer interposed between the first bonding layer and the second bonding layer and in contact with side surfaces of the first conductive pattern and the second conductive pattern, a mold layer covering a side surface of the second semiconductor die and an upper surface of the first semiconductor die, and an external connection terminal bonded to the lower surface of the first semiconductor die, wherein the first bonding layer and the second bonding layer are formed of SiCN, the first bonding layer or the second bonding layer has a first thickness, the silicon oxide layer has a second thickness smaller than the first thickness, at least one pore is disposed in the silicon oxide layer, and the pore is spaced apart from the first conductive pattern and the second conductive pattern.

In some implementations, a method of fabricating a semiconductor package includes preparing a first wafer including a first bonding layer that is formed of SiCN and is disposed on an uppermost surface thereof, grinding the first bonding layer, removing CN from a surface of the first bonding layer to form a dangling bond with a silicon atom, preparing a second semiconductor die including a second bonding layer that is formed of SiCN and is disposed on an uppermost surface thereof, removing CN from a surface of the second bonding layer to form a dangling bond with a silicon atom, coupling an OH group to the dangling bond of the silicon atom on the surface of the first bonding layer, coupling an OH group to the dangling bond of the silicon atom on the surface of the second bonding layer, inverting the second semiconductor die to place the second semiconductor die on the first wafer so that the second bonding layer is in contact with the first bonding layer, and performing a first bonding process to form a silicon oxide layer between the second bonding layer and the first bonding layer, and bonding the second bonding layer and the first bonding layer.

### BRIEF DESCRIPTION OF THE DRAWINGS

Example implementations will be more clearly understood from the following brief description, taken in conjunction with the accompanying drawings. The accompanying drawings represent non-limiting, example implementations as described herein.

FIG. 1 is a cross-sectional view of an example of a semiconductor package.

FIG. 2 is an example enlarged view of a portion ‘P1’ of FIG. 1.

FIGS. 3A and 3B are example enlarged views of a portion ‘P2’ of FIG. 2.

FIG. 4 is an example enlarged view of a portion ‘P3’ of FIG. 3A or 3B.

FIG. 5 is a cross-sectional view of an example of a semiconductor package.

FIG. 6 is an example enlarged view of a portion ‘P4’ in FIG. 5.

FIG. 7 is a flowchart illustrating an example of a method of fabricating a semiconductor package.

FIGS. 8A to 8I are cross-sectional views illustrating an example of a method of fabricating the semiconductor package of FIG. 1.

FIG. 9A is an example enlarged view of a portion ‘P5’ of FIG. 8B or 8D.

FIG. 9B is an example enlarged view of a portion ‘P9’ of FIG. 9A.

FIG. 10 is an example enlarged view of a portion ‘P6’ of FIG. 8C or 8E.

FIG. 11A is an example enlarged view of a portion ‘P7’ of FIG. 8F.

FIG. 11B is an example enlarged view of a portion ‘P10’ of FIG. 11A.

FIG. 12A is an example enlarged view of a portion ‘P8’ of FIG. 8G.

FIG. 12B is an example enlarged view of a portion ‘P11’ of FIG. 12A.

FIG. 13 is an example enlarged view of a portion ‘P8’ of FIG. 8G.

### DETAILED DESCRIPTION

Hereinafter, to explain the concepts in more detail, implementations according to the concepts will be described with reference to the accompanying drawings.

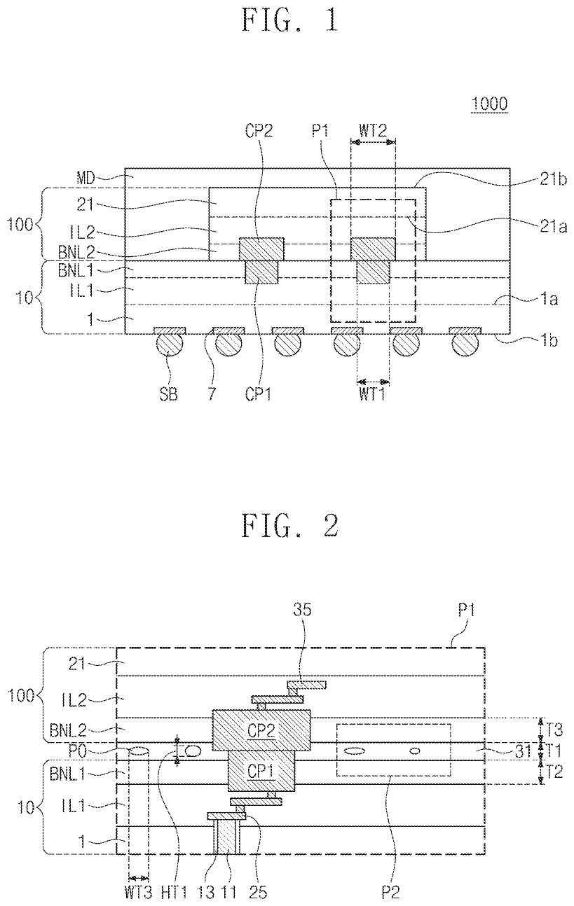

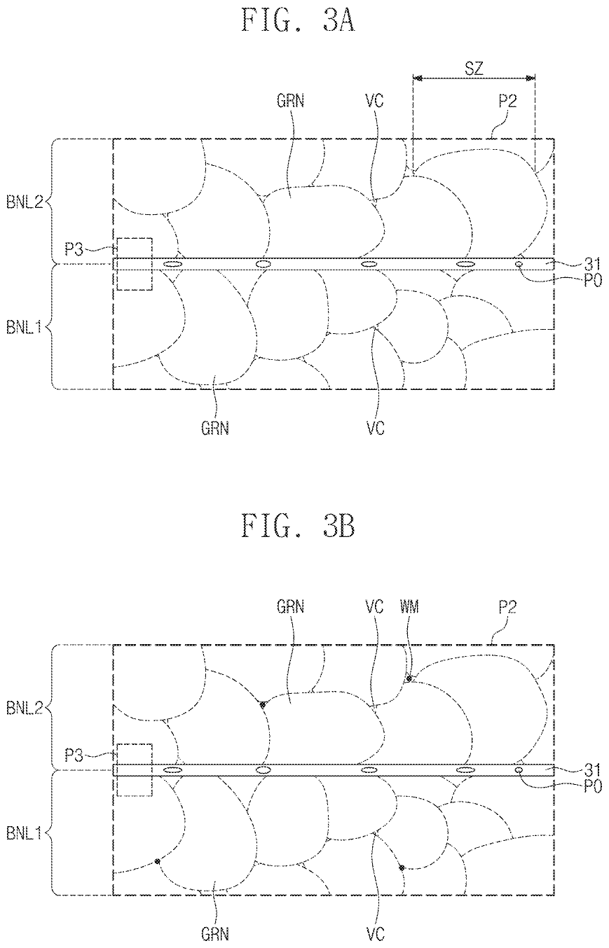

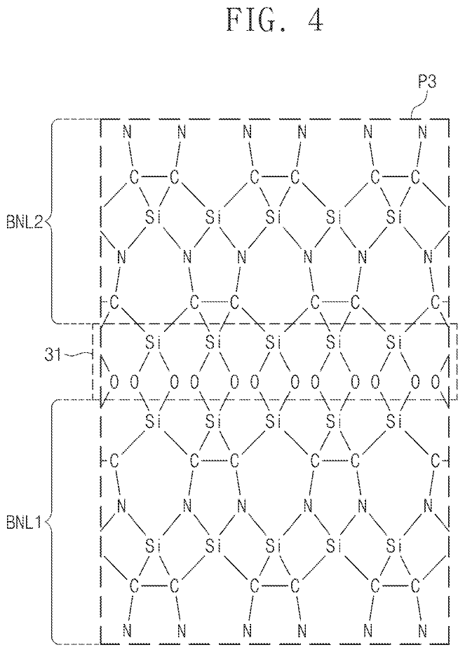

FIG. 1 is a cross-sectional view of an example of a semiconductor package. FIG. 2 is an example enlarged view of a portion ‘P1’ of FIG. 1. FIGS. 3A and 3B are example enlarged views of a portion ‘P2’ of FIG. 2. FIG. 4 is an example enlarged view of a portion ‘P3’ of FIG. 3A or 3B.

Referring to FIGS. 1 and 2, a semiconductor package 1000 includes a first semiconductor die 10, a second semiconductor die 100, and a mold layer MD. In this specification, ‘semiconductor die’ may also be referred to as ‘semiconductor chip’. The first semiconductor die 10 may be a logic circuit chip or a memory chip such as a flash memory chip, DRAM chip, SRAM chip, EEPROM chip, PRAM chip, MRAM chip, or ReRAM chip. The first semiconductor die 10 includes a first substrate 1, a first interlayer insulating layer IL1, and a first bonding layer BNL1 sequentially stacked. The first substrate 1 may be a semiconductor substrate formed of a semiconductor such as silicon, a silicon on insulator (SOI) substrate, and/or an insulating substrate. The first substrate 1 includes a first surface 1a and a second surface 1b opposite to each other. Although not shown, a plurality of transistors may be disposed on the first surface 1a of the first substrate 1.

A first interlayer insulating layer IL1 is disposed on the first surface 1a of the first substrate 1. The first interlayer insulating layer IL1 may have a single layer or multi-layered structure of at least one of silicon oxide, silicon nitride, and silicon oxynitride. Multi-layered first wirings 25 may be disposed in the first interlayer insulating layer IL1. The first wirings 25 may be formed of polysilicon doped with impurities or a metal such as aluminum, tungsten, titanium, or copper. The first wirings 25 and the transistors may configure various circuits.

A plurality of first conductive pads 7 may be disposed on the second surface 1b of the first substrate 1. Although not shown, an insulating layer may be interposed between the second surface 1b of the first substrate 1 and the first conductive pads 7. External connection terminals SB may be respectively bonded to the first conductive pads 7. The external connection terminals SB may include at least one of conductive bumps and solder balls. The external connection terminals SB may include at least one metal among copper, nickel, tin, and silver.

A first through-via 11 may pass through the first substrate 1 and a portion of the first interlayer insulating layer IL1 to connect the first conductive pads 7 to the first wirings 25. The first through-via 11 may include a metal material such as copper, tungsten, or titanium. A first through insulating layer 13 may be interposed between the first through-via 11 and the first substrate 1. The first through insulating layer 13 may be formed of, for example, silicon oxide.

A first bonding layer BNL1 may be formed of silicon carbon nitride (SiCN). The first bonding layer BNL1 may also be referred to as a ‘first SiCN layer’. A first conductive pattern CP1 may pass through a portion of the first bonding layer BNL1 and the first interlayer insulating layer IL1. The first conductive pattern CPI may include, for example, copper.

The second semiconductor die 100 may be a different chip from the first semiconductor die 10. The second semiconductor die 100 may be a logic circuit chip or a memory chip such as a flash memory chip, DRAM chip, SRAM chip, EEPROM chip, PRAM chip, MRAM chip, or ReRAM chip. The second semiconductor die 100 includes a second substrate 21, a second interlayer insulating layer IL2, and a second bonding layer BNL2 sequentially stacked. The second substrate 21 may be a semiconductor substrate formed of a semiconductor such as silicon, a silicon on insulator (SOI) substrate, and/or an insulating substrate. The second substrate 21 includes a first surface 21a and a second surface 21b opposite to each other. Although not shown, a plurality of transistors may be disposed on the first surface 21a of the second substrate 21. The first surface 21a of the second substrate 21 faces the first semiconductor die 10.

A second interlayer insulating layer IL2 is disposed on the first surface 21a of the second substrate 21. The second interlayer insulating layer IL2 may have a single layer or multi-layered structure of at least one of silicon oxide, silicon nitride, and silicon oxynitride. Multi-layered second wirings 35 may be disposed in the second interlayer insulating layer IL2. The second wirings 35 may be formed of polysilicon doped with impurities or a metal such as aluminum, tungsten, titanium, or copper. The first wirings 25 and the transistors may configure various circuits.

A second bonding layer BNL2 may be formed of silicon carbon nitride (SiCN). The second bonding layer BNL2 may also be referred to as a ‘second SiCN layer’. The second conductive pattern CP2 may pass through the second bonding layer BNL2 and a portion of the second interlayer insulating layer IL2. The second conductive pattern CP2 may include, for example, copper.

The first conductive pattern CP1 and the second conductive pattern CP2 may be in contact with each other. The first conductive pattern CP1 may have a first width WT1. The second conductive pattern CP2 may have a second width WT2 different from the first width WT1. For example, the second width WT2 may be greater than the first width WT1. Conversely, the second width WT2 may be smaller than the first width WT1. This difference in width may improve the misalignment margin. There is an interface between the first conductive pattern CP1 and the second conductive pattern CP2 to be integrally formed with each other.

Referring to FIG. 2, a silicon oxide layer 31 is interposed between the first semiconductor die 10 and the second semiconductor die 100. The silicon oxide layer 31 may be interposed between the first bonding layer BNL1 and the second bonding layer BNL2 and may be in direct contact with the first bonding layer BNL1 and the second bonding layer BNL2. The silicon oxide layer 31 may also be referred to as an ‘insulating layer’ or a ‘bonding interface layer’. The silicon oxide layer 31 may be in contact with a side surface of the first conductive pattern CP1. The silicon oxide layer 31 may be in contact with a side surface of the second conductive pattern CP2. The silicon oxide layer 31 may have a first thickness T1. The first bonding layer BNL1 may have a second thickness T2. The second bonding layer BNL2 may have a third thickness T3. The first thickness T1 may be smaller than the second thickness T2 and/or the third thickness T3. The second thickness T2 and the third thickness T3 may have the same or different thicknesses.

At least one pore PO may be disposed in the silicon oxide layer 31. The pore PO may be spaced apart from the first bonding layer BNL1 and the second bonding layer BNL2. The pore PO may be spaced apart from the first conductive pattern CP1 and the second conductive pattern CP2. The pore PO may have a first height HT1. The first height HT1 may be 1 Å to 2 nm. The pore PO may have a third width WT3. The third width WT3 may be 1 nm to 100 nm. The pore PO may also be referred to as ‘void’ or ‘vacancy’.

Referring to FIGS. 3A and 3B, each of the first conductive pattern CPI and the second conductive pattern CP2 may have SiCN grains GRN. A coupling relationship between silicon atoms, carbon atoms, and nitrogen atoms in each of the SiCN grains GRN may have, for example, a t-SiCN crystal structure as shown in FIG. 4. Alternatively, a crystal structure of each of the SiCN grains (GRN) may be c-SiCN, o-SiCN or h-SiCN. The SiCN grains GRN may have an average size SZ (here, a size may mean a diameter, width, or height). A first height HT1 of the pores PO may be smaller than the average size SZ of the SiCN grains GRN. A gap VC may exist at an interface between the SiCN grains GRN. H₂O, which is a water molecule WM, may exist (or be trapped) in the interface or gap VC between the SiCN grains GRN.

A width of the second semiconductor die 100 may be smaller than that of the first semiconductor die 10, and an upper surface of the first semiconductor die 10 may be partially exposed. The mold layer MD may cover upper and side surfaces of the second semiconductor die 100 and an upper surface of the first semiconductor die 10. The mold layer MD may include an insulating resin such as an epoxy-based molding compound (EMC). The mold layer MD may further include a filler, and the filler may be dispersed in the insulating resin. The filler may include, for example, silicon oxide (SiO₂).

In the semiconductor package 1000, ultrafine pores PO are formed in the silicon oxide layer 31. While the pore PO is formed, the water molecules WM may cause compressive stress toward the silicon oxide layer 31 in the first bonding layer BNL1 and the second bonding layer BNL2, and thus adhesive strength and adhesion area between the first bonding layer BNL1 and the second bonding layer BNL2 may be improved. In addition, as shown in FIG. 4, the silicon oxide layer 31 may improve bonding strength between the first bonding layer BNL1 and the second bonding layer BNL2. Accordingly, the semiconductor package 1000 having improved reliability may be provided.

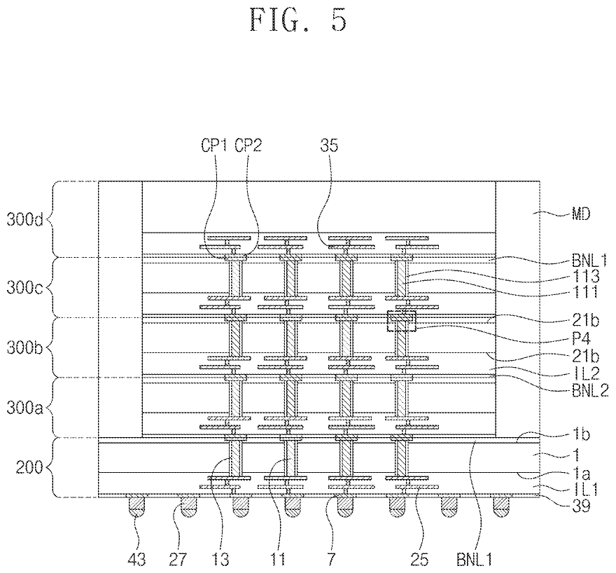

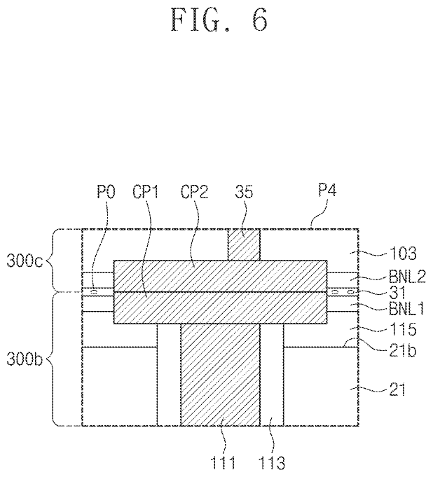

FIG. 5 is a cross-sectional view of an example of a semiconductor package. FIG. 6 is an example enlarged view of a portion ‘P4’ in FIG. 5.

Referring to FIGS. 5 and 6, a semiconductor package 1001 according to the present example may include second to fifth semiconductor dies 300a, 300b, 300c, and 300d sequentially stacked on a first semiconductor die 200. The first semiconductor die 10 may be a different type of chip from the second to fifth semiconductor dies 300a, 300b, 300c, and 300d. The first semiconductor die 200 may be, for example, a logic circuit chip or a buffer die. The second to fifth semiconductor dies 300a, 300b, 300c, and 300d may be the same memory chips as each other. The memory chip may be, for example, DRAM, NAND Flash, SRAM, MRAM, PRAM, or RRAM. Although a structure in which one logic circuit chip and four memory chips are stacked is disclosed in this example, the number of stacked logic circuit chips and memory chips is not limited thereto and may be various. The first semiconductor die 10 may have a wider width than the second to fifth semiconductor dies 300a, 300b, 300c, and 300d. The semiconductor package 1001 may be a high bandwidth memory (HBM) chip.

A mold layer MD may cover an upper surface of the first semiconductor die 200 and side surfaces of the second to fifth semiconductor dies 300a, 300b, 300c, and 300d. An upper surface of the mold layer MD may be coplanar with an upper surface of the fifth semiconductor die 300d.

The first semiconductor die 200 may include a first substrate 1. The first substrate 1 may include a first surface 1a and a second surface 1b facing each other. A first interlayer insulating layer IL1 may be disposed on the first surface 1a. First transistors and multi-layered first wirings 5 may be disposed in the first interlayer insulating layer IL1. First conductive pads 7 may be disposed on the first interlayer insulating layer IL1. First conductive bumps 27 may be respectively bonded to the first conductive pads 7. The first conductive bumps 27 may include, for example, copper. A solder layer 43 may be bonded under the first conductive bumps 27. The solder layer 43 may include SnAg, for example. The first interlayer insulating layer IL1 may be covered with a first passivation layer 39. The first passivation layer 39 may include SiN, for example. The second surface 1b of the first substrate 1 may be covered with a first bonding layer BNL1. As shown in FIG. 6, a back insulating layer 115 may be interposed between the first bonding layer BNL1 and the second surface 1b of the first substrate 1. The back insulating layer 115 may be formed of, for example, silicon oxide. The first substrate 1 and a portion of the first interlayer insulating layer IL1 may be penetrated by the first through-via 11. A first through insulating layer 13 may be interposed between the first through-via 11 and the first substrate 1. A first conductive pattern CP1 may be disposed in the first bonding layer BNL1.

Each of the second to fifth semiconductor dies 300a, 300b, 300c, and 300d may include a second substrate 21. The second substrate 21 may include a first surface 21a and a second surface 21b that face each other. A second interlayer insulating layer IL2 may be disposed on the first surface 21a of the second substrate 21. Second transistors and multi-layered second wirings 35 may be disposed in the second interlayer insulating layer IL2. Second conductive patterns CP2 may be disposed on the second interlayer insulating layer IL2. The second interlayer insulating layer IL2 may be covered with a second bonding layer BNL2. A first bonding layer BNL1 and a first conductive pattern CP1 are disposed on the second surface 21b of the second substrate 21. The first conductive pattern CP1 may pass through the first bonding layer BNL1. As shown in FIG. 6, a back insulating layer 115 may be interposed between the first bonding layer BNL1 and the second surface 1b of the second substrate 21. Each of portions of the back insulating layer 115, the second substrate 21, and the second interlayer insulating layer IL2 may be penetrated by the second through-via 111 in the second to fourth semiconductor dies 300a, 300b, and 300c. A second through insulating layer 113 may be interposed between the second through-via 111 and the second substrate 21. The fifth semiconductor die 300d may not include the second through-via 111 and the second through insulating layer 113 and may be excluded. The first to fifth semiconductor dies 10, 300a, 300b, 300c, and 300d may be in contact with each other. The first conductive pattern CP1 and the second conductive pattern CP2 may be in contact with each other. Widths of the first conductive pattern CP1 and the second conductive pattern CP2 may be the same.

Referring to FIGS. 5 and 6, a silicon oxide layer 31 is interposed between the first to fifth semiconductor dies 200, 300a, 300b, 300c, and 300d. At least one pore PO is disposed in the silicon oxide layer 31. The pore PO may be spaced apart from the first bonding layer BNL1 and the second bonding layer BNL2. The pore PO may be spaced apart from the first conductive pattern CP1 and the second conductive pattern CP2. As described with reference to FIG. 2, the pore PO may have a first height HT1. The first height HT1 may be 1 Å to 2 nm. The pore PO may have a third width WT3. The third width WT3 may be 1 nm to 100 nm. Other configurations may be the same/similar to those described with reference to FIGS. 1 to 4.

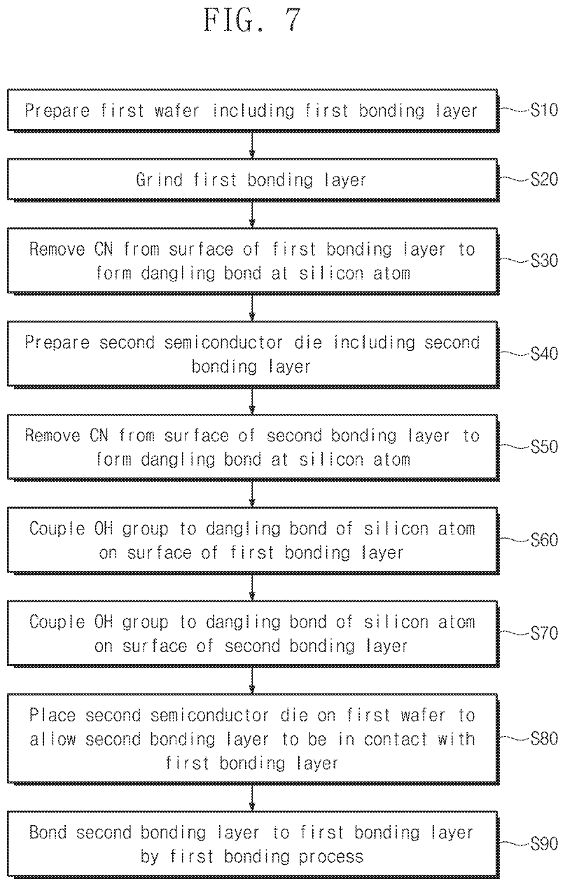

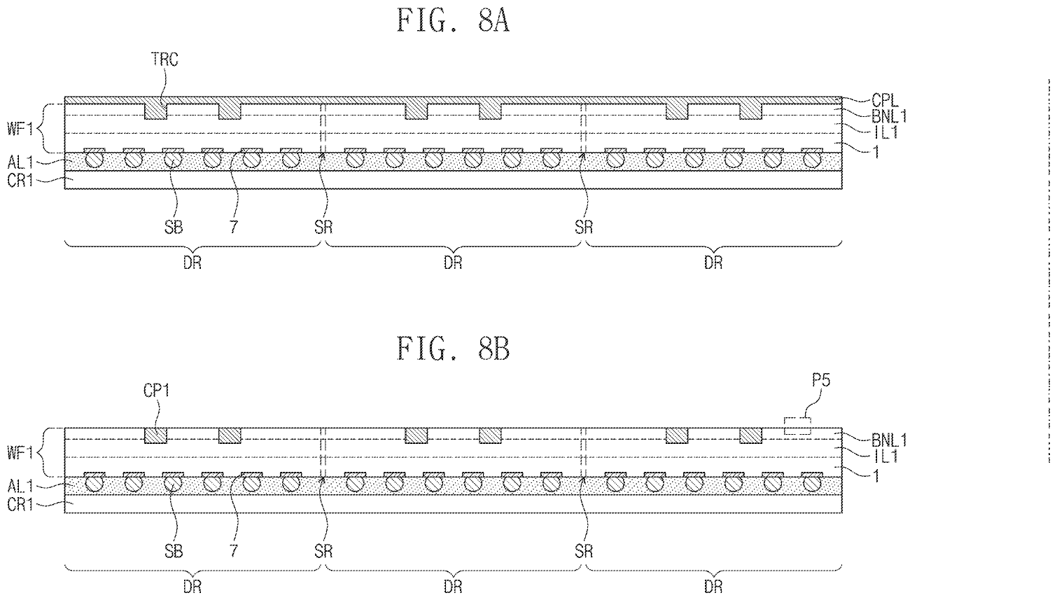

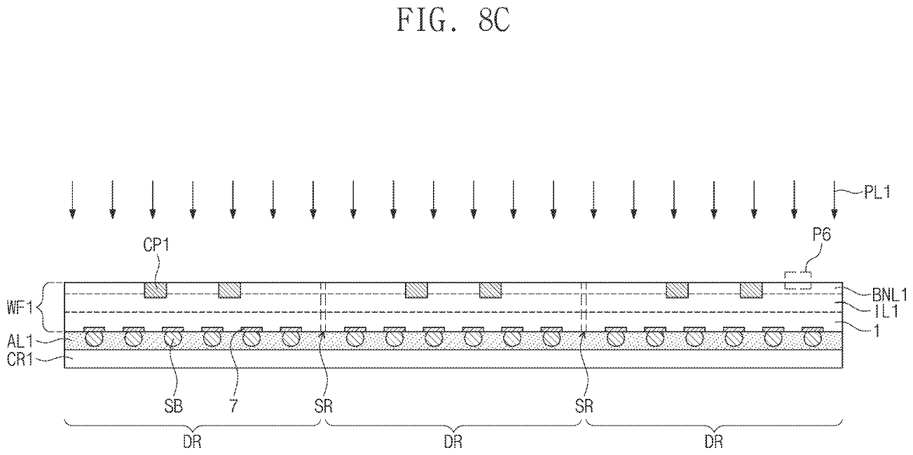

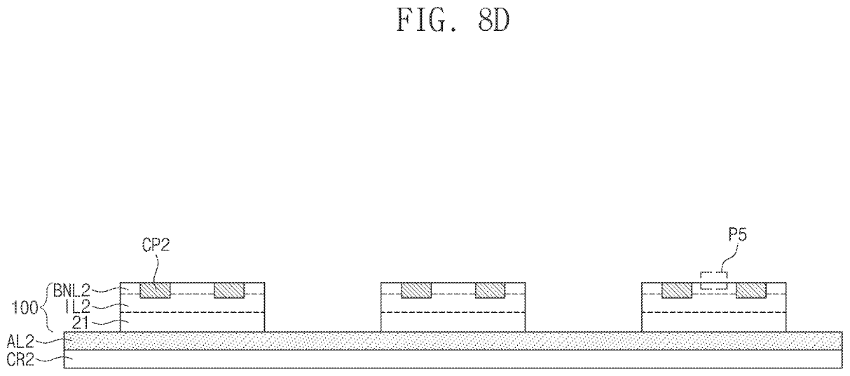

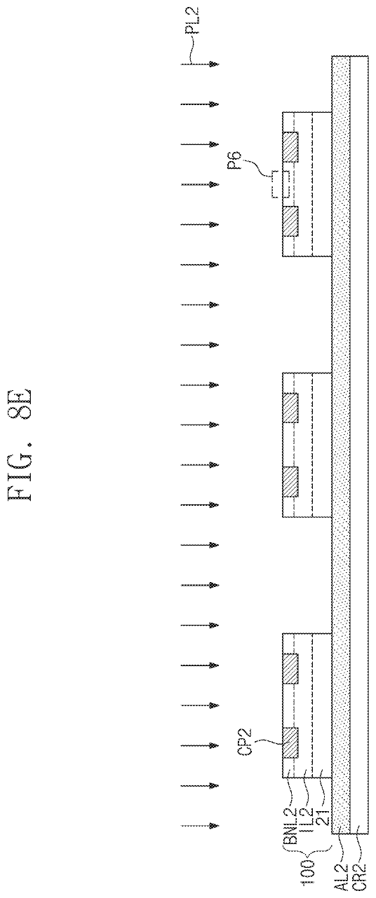

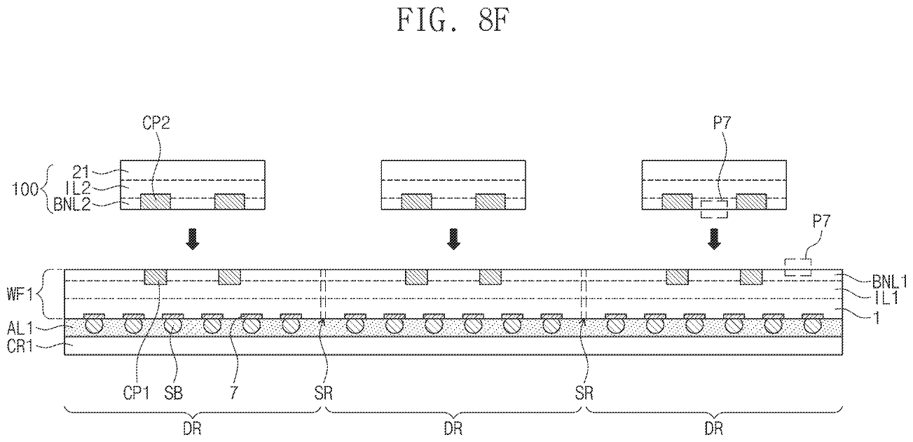

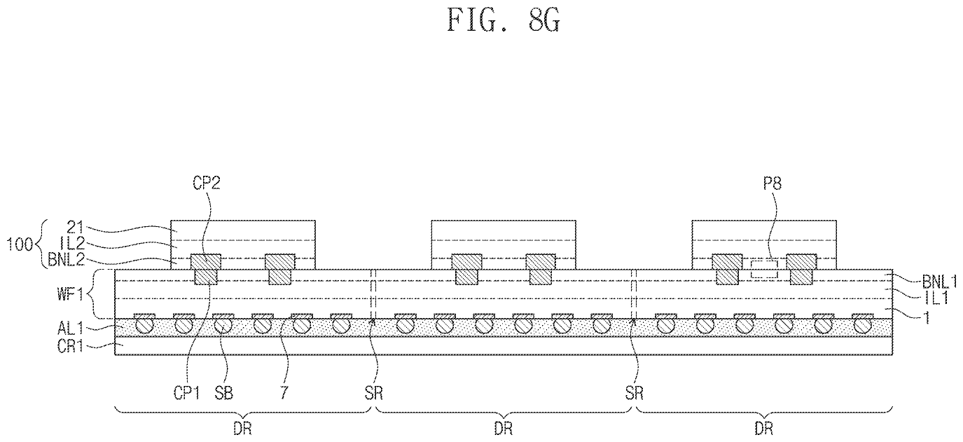

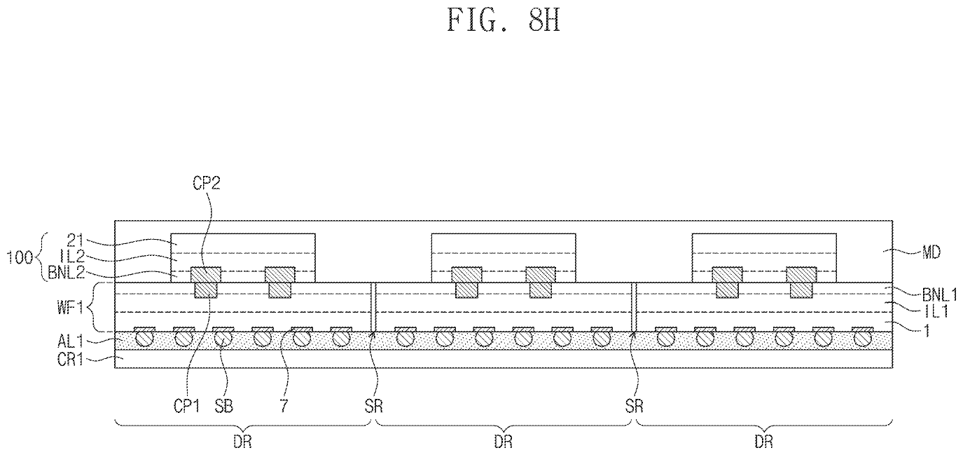

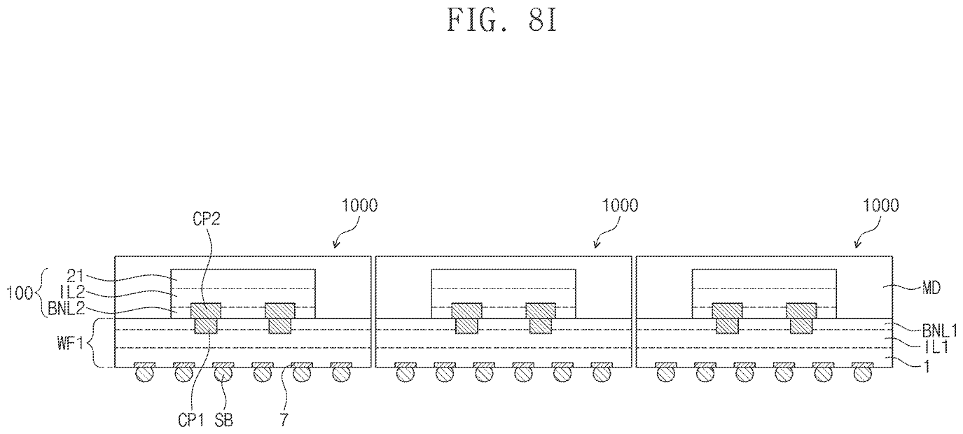

FIG. 7 is a flowchart illustrating an example of a method of fabricating a semiconductor package. FIGS. 8A to 8I are cross-sectional views illustrating an example of a method of fabricating the semiconductor package of FIG. 1.

Referring to FIGS. 7 and 8A, a first wafer WF1 including a first bonding layer BNL1 disposed on an uppermost surface thereof is prepared in a first step S10. The first wafer WF1 may include a plurality of device regions DR and a separation region SR therebetween. In each of the device regions DR, the first wafer WF1 may have the same/similar structure as the first semiconductor die 10 described with reference to FIGS. 1 and 2. The first wafer WF1 may include a first interlayer insulating layer IL1 and a first bonding layer BNL1 sequentially stacked on the first substrate 1. The first bonding layer BNL1 is formed of SiCN. As shown in FIG. 3A, the first bonding layer BNL1 may include a plurality of SiCN grains GRN. First conductive pads 7 and external connection terminals SB may be bonded to the lower surface of the first substrate 1. The first wafer WF1 may be attached to the first carrier substrate CRI through a sacrificial adhesive layer AL1. The sacrificial adhesive layer ALI may include a thermosetting resin or a photocurable resin. Trenches TRC for forming first conductive patterns CP1 are formed in portions of the first bonding layer BNL1 and the first interlayer insulating layer IL1. A plating process is performed on the first bonding layer BNL1 to form a first conductive layer CPL to fill the trenches TRC. The first conductive layer CPL may include, for example, copper.

Referring to FIGS. 7 and 8B, a grinding process is performed on the first conductive layer CPL to form first conductive patterns CP1 and expose an upper surface of the first bonding layer BNL1. In this case, the first bonding layer BNL1 is also ground in a second step S20.

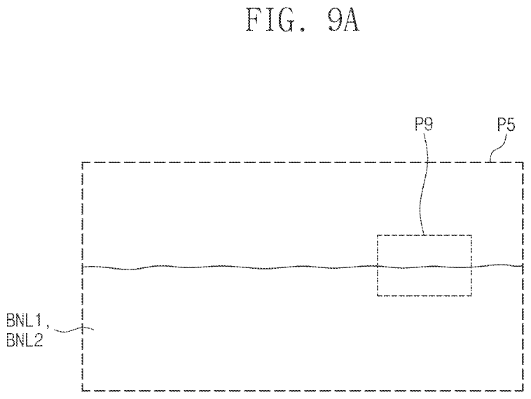

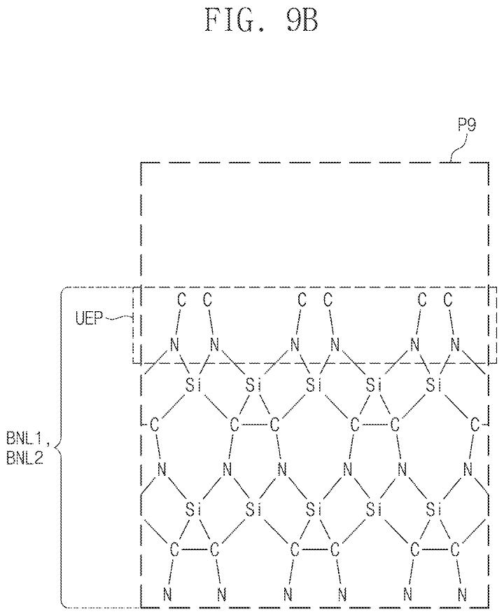

FIG. 9A is an example enlarged view of a portion ‘P5’ of FIG. 8B or 8D. FIG. 9B is an example enlarged view of a portion ‘P9’ of FIG. 9A.

Referring to FIGS. 7 and 8B and 9A and 9B, while the upper surface of the first bonding layer BNL1 is ground, an upper surface of the first bonding layer BNL1 looks macroscopically flat as shown in FIG. 8B. However, as shown in FIG. 9A, the upper surface of the first bonding layer BNL1 has a surface roughness of several Å or several nanometers. A CN group may be coupled to a silicon (Si) atom on a surface UEP of the first bonding layer BNL1 as shown in FIG. 9B.

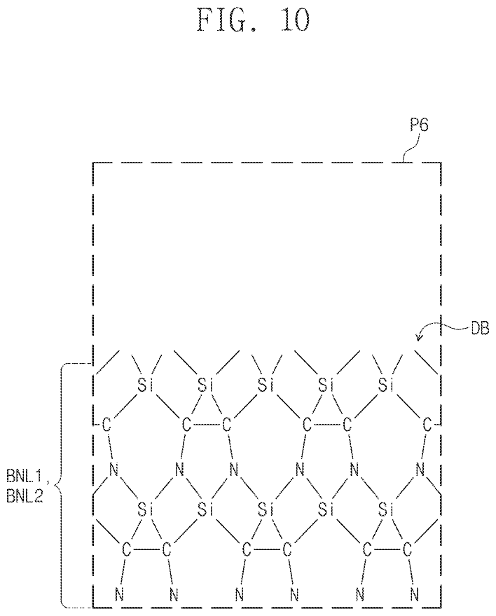

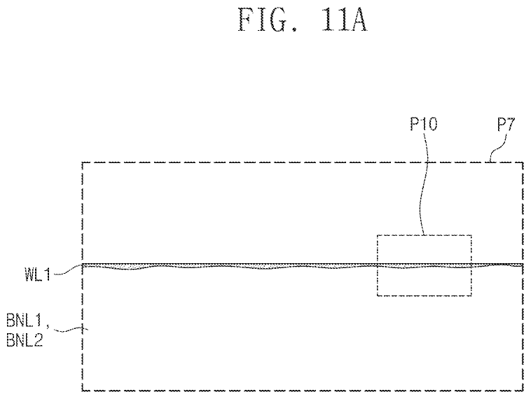

FIG. 10 is an example enlarged view of a portion ‘P6’ of FIG. 8C or 8E.

Referring to FIGS. 7, 8C, and 10, the CN group is removed from the surface UEP of the first bonding layer BNL1 of FIG. 9B and a dangling bond DB is formed with silicon (Si) atoms in a third step S30. To this end, a first plasma process PL1 is performed on the first bonding layer BNL1 in the state of FIG. 8B. The first plasma process PL1 may be performed using at least one of oxygen, nitrogen, and argon. The third step S30 may also be referred to as ‘activating the surface of the first bonding layer BNL1’.

Referring to FIGS. 7 and 8D, a second semiconductor die 100 including the second bonding layer BNL2 disposed on an uppermost surface thereof is prepared in a fourth step S40. The second semiconductor die 100 may have the same/similar structure to that described with reference to FIGS. 1 and 2. The second semiconductor die 100 may include a second interlayer insulating layer IL2 and a second bonding layer BNL2 sequentially stacked on the second substrate 21. The second bonding layer BNL2 is formed of SiCN. As shown in FIG. 3A, the second bonding layer BNL2 may include a plurality of SiCN grains GRN. A second conductive pattern CP2 is disposed in the second bonding layer BNL2. The second semiconductor die 100 may be provided in the plural and may be attached to a second carrier substrate CR2 through a second sacrificial adhesive layer AL2.

In a grinding process for fabricating the second conductive pattern CP2, an upper surface of the second bonding layer BNL2 may also be ground. Accordingly, the upper surface of the second bonding layer BNL2 looks flat macroscopically as shown in FIG. 8D, but has surface roughness of several Å or several nanometers as shown in FIG. 9A. A CN group may be coupled to a silicon (Si) atom on a surface UEP of the second bonding layer BNL2 as shown in FIG. 9B.

Referring to FIGS. 7 and 8E, as shown in FIG. 10, CN is removed from the surface of the second bonding layer BNL2 and dangling bonds are formed with silicon (Si) atoms in a fifth step S50. To this end, a second plasma process PL2 is performed on the second bonding layer BNL2. The second plasma process PL2 may be performed using at least one of oxygen, nitrogen, and argon. The fifth step S50 may also be referred to as ‘activating the surface of the second bonding layer BNL2’.

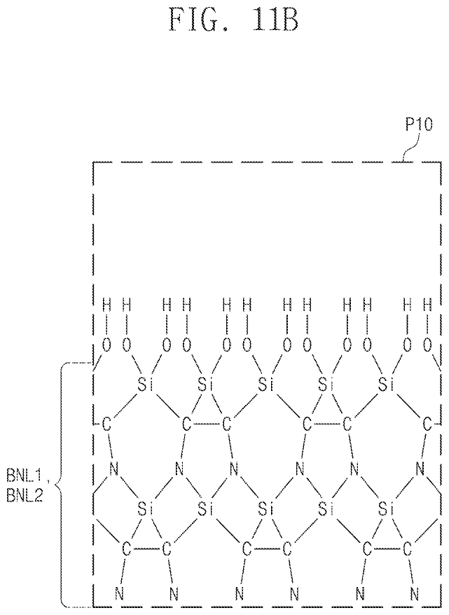

FIG. 11A is an example enlarged view of a portion ‘P7’ of FIG. 8F. FIG. 11B is an example enlarged view of a portion ‘P10’ of FIG. 11A.

Referring to FIGS. 7, 8F, 11A, and 11B, an OH group is coupled to the dangling bond DB of the silicon atom on a surface of the first bonding layer BNL1 in a sixth step S60. An OH group is coupled to the dangling bond DB of the silicon atom on the surface of the second bonding layer BNL2 in a seventh step S70. The sixth step S60 may include performing a cleaning process on the upper surface of the first bonding layer BNL1 using deionized water. In the cleaning process, deionized water WL1 may remove particles on the first bonding layer BNL1, and at the same time, an OH group of the water molecule of the deionized water WL1 may be coupled to a dangling bond DB of the silicon atom. Step of S70 may include performing a cleaning process on the upper surface of the second bonding layer BNL2 using deionized water. In the cleaning process, the deionized water WL1 may remove particles on the second bonding layer BNL2, and at the same time, an OH group of the water molecule of the deionized water WL1 may be coupled to the dangling bond DB of the silicon atom.

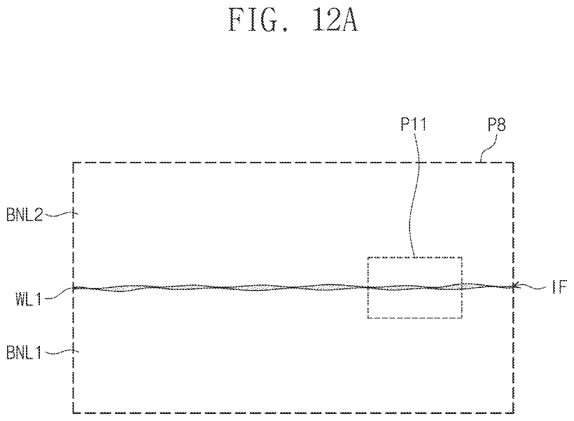

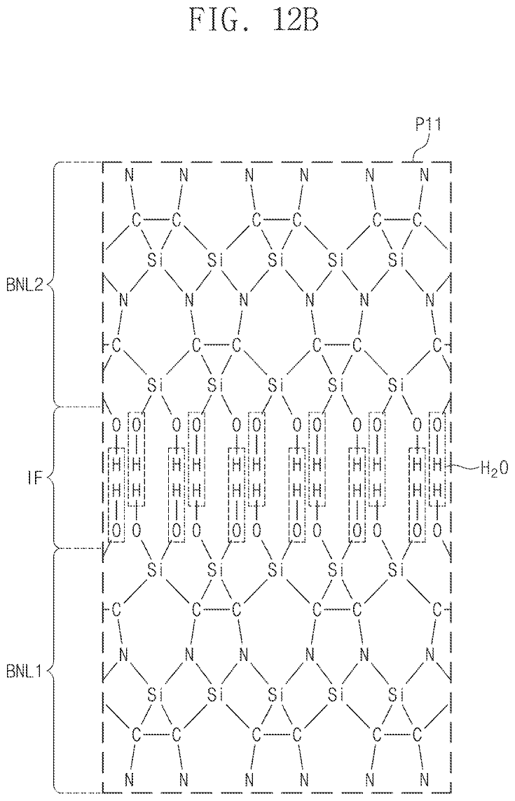

FIG. 12A is an example enlarged view of a portion ‘P8’ of FIG. 8G. FIG. 12B is an example enlarged view of a portion ‘P11’ of FIG. 12A.

Referring to FIGS. 7, 8F, 8G, 12A, and 12B, the second semiconductor die 100 is turned over and is placed on the first wafer WF1 so that the second bonding layer BNL2 is in contact with the first bonding layer BNL1 in an eighth step S80. As a result, as shown in FIG. 12A, deionized water WL1 or water molecules may exist in an interface IF between the second bonding layer BNL2 and the first bonding layer BNL1. Alternatively, as shown in FIG. 12B, OH groups may be adjacent to each other at the interface IF between the second bonding layer BNL2 and the first bonding layer BNL1. In the eighth step S80, the first conductive pattern CP1 and the second conductive pattern CP2 may be in contact with each other.

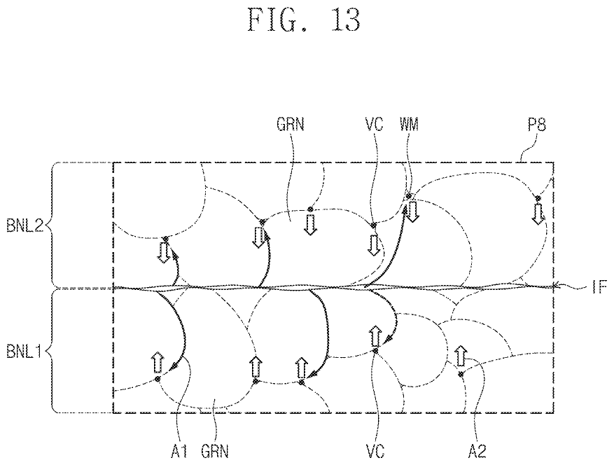

FIG. 13 is an example enlarged view of a portion ‘P8’ of FIG. 8G.

Referring to FIGS. 7, 8G, and 13, a first bonding process is performed to form a silicon oxide layer 31 between the second bonding layer BNL2 and the first bonding layer BNL1 and to bond the second bonding layer BNL2 and the first bonding layer BNL1 in a ninth step S90. The first bonding process may be referred to as a first thermocompression bonding process. The first bonding process may be performed at 100° C. to 150° C. By the first bonding process, the OH group on the surface of the second bonding layer BNL2 reacts with the OH group on the surface of the first bonding layer BNL1 to generate H₂O, which is a water molecule WM, and remaining oxygen atoms O is covalently coupled with silicon atoms on the surface of the second bonding layer BNL2 and silicon atoms on the surface of the first bonding layer BNL1, thereby forming the silicon oxide layer 31.

The H₂O, which is a water molecule WM formed in the first bonding process, may penetrate into the gap VC along the interface between the SiCN grains GRN (along a first arrow A1) to induce compressive stress toward the interface IF between the first bonding layer BNL1 and the second bonding layer BNL2 (in a direction of a second arrow A2). Accordingly, a distance between the first bonding layer BNL1 and the second bonding layer BNL2 may be reduced, an adhesion area may be increased, and adhesive strength may be improved. A covalent bonding area between oxygen atoms and silicon atoms of the silicon oxide layer 31 may increase due to the compressive stress. As a result, adhesive strength between the first semiconductor die 10 and the second semiconductor die 100 in the semiconductor package 1000 finally formed may be improved. This may reduce process defects and improve yield.

As the water molecules WM are discharged in the first bonding process, at least one pore PO may be formed in the silicon oxide layer 31 as shown in FIG. 3A. As described with reference to FIG. 2, the pore PO may have a first height HT1. The first height HT1 may be 1 Å to 2 nm. The pore PO may have a third width WT3. The third width WT3 may be 1 nm to 100 nm. The water molecules WM may move along the interface between the first wafer WF1 and the second semiconductor die 100 and may escape to an edge of the second semiconductor die 100.

Some of the water molecules WM may remain trapped in the gap VC between the SiCN grains GRN in the first bonding layer BNL1 and the second bonding layer BNL2, as shown in FIG. 3B.

Subsequently, although not shown in FIG. 7, referring to FIG. 8G, a second bonding process may be performed after the first bonding process to couple the first conductive pattern CP1 and the second conductive pattern CP2 to each other. The second bonding process may be referred to as a second thermal compression bonding process. The second bonding process may be performed at a temperature at which a metal (e.g., copper) constituting the first conductive pattern CP1 and the second conductive pattern CP2 is diffused or melted. The second bonding process may be performed at a temperature of, for example, 250° C. to 350° C.

Subsequently referring to FIG. 8H, a mold layer MD is formed on the first wafer WF1. Then, a singulation process is performed as shown in FIG. 8I to cut the separation region SR of the first wafer WF1 and the mold layer MD thereon. As a result, a semiconductor packages 1000 of FIG. 1 may be manufactured.

According to the method of fabricating the semiconductor package, the adhesive strength between the first semiconductor die 10 and the second semiconductor die 100 may be improved. This may reduce process defects and improve yield.

In the semiconductor package, the silicon oxide layer is disposed between the first semiconductor die including the first bonding layer and the second semiconductor including the second bonding layer, and the ultrafine pores are formed in the silicon oxide layer. While the pore is formed, water molecules may cause compressive stress in the first bonding layer and the second bonding layer, and thus the adhesive strength between the first bonding layer and the second bonding layer may be improved. Accordingly, the semiconductor package with the improved reliability may be provided.

The method of fabricating the semiconductor package may improve the adhesive strength between the first semiconductor die and the second semiconductor die. This may reduce the process defects and improve the yield.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While implementations are described above, a person skilled in the art may understand that many modifications and variations are made without departing from the spirit and scope of the concepts defined in the following claims. Accordingly, the example implementations of the concepts should be considered in all respects as illustrative and not restrictive, with the spirit and scope of the concepts being indicated by the appended claims.

1. A semiconductor package comprising:
a first semiconductor die including a first substrate and a first bonding layer, the first bonding layer being on the first substrate;
a second semiconductor die disposed on the first semiconductor die, the second semiconductor die including a second substrate and a second bonding layer, the second bonding layer being under the second substrate; and
a silicon oxide layer interposed between the first semiconductor die and the second semiconductor die,
wherein at least one pore is disposed in the silicon oxide layer, and
wherein the at least one pore has a height of 1 Å to 2 nm.

2. The semiconductor package of claim 1, wherein the at least one pore has a width of 1 nm to 100 nm.

3. The semiconductor package of claim 1, wherein the first bonding layer includes a first plurality of silicon carbon nitride (SiCN) grains and the second bonding layer includes a second plurality of SiCN grains, and
wherein an average size of the first plurality of SiCN grains or an average size of the second plurality of SiCN grains is greater than a height of the at least one pore. Herewith

4. The semiconductor package of claim 3, wherein at least one of the first bonding layer or the second bonding layer includes a plurality of water molecules trapped between at least one of the first plurality of SiCN grains or the second plurality of SiCN grains, respectively.

5. The semiconductor package of claim 1, wherein the first semiconductor die includes a first conductive pattern disposed on the first substrate, the first conductive pattern extending through the first bonding layer,
wherein the second semiconductor die includes a second conductive pattern disposed under the second substrate, the second conductive pattern extending through the second bonding layer, the second conductive pattern being in contact with the first conductive pattern, and
wherein the at least one pore is spaced apart from the first conductive pattern and the second conductive pattern.

6. The semiconductor package of claim 5, wherein a width of the first conductive pattern is different from a width of the second conductive pattern.

7. The semiconductor package of claim 1, wherein the silicon oxide layer has a first thickness, and
Wherein at least one of the first bonding layer or the second bonding layer has a second thickness greater than the first thickness.

8. The semiconductor package of claim 1, wherein the at least one pore is spaced apart from the first bonding layer and the second bonding layer.

9. A semiconductor package comprising:
a first semiconductor die including a first substrate and a first bonding layer, the first bonding layer being on the first substrate;
a second semiconductor die disposed on the first semiconductor die, the second semiconductor die including a second substrate and a second bonding layer, the second bonding layer being under the second substrate; and
a silicon oxide layer interposed between the first semiconductor die and the second semiconductor die,
wherein at least one pore is disposed in the silicon oxide layer,
wherein the first bonding layer and the second bonding layer include a plurality of silicon carbon nitride (SiCN) grains, and
wherein a height of the at least one pore is smaller than an average size of the plurality of SiCN grains.

10. The semiconductor package of claim 9, wherein the at least one pore has a height of 1 Å to 2 nm.

11. The semiconductor package of claim 9, wherein the at least one pore has a width of 1 nm to 100 nm.

12. The semiconductor package of claim 9, wherein the first semiconductor die includes a first conductive pattern disposed on the first substrate, the first conductive pattern extending through the first bonding layer,
wherein the second semiconductor die includes a second conductive pattern disposed under the second substrate, the second conductive pattern extending through the second bonding layer, the second conductive pattern being in contact with the first conductive pattern, and
wherein the at least one pore is spaced apart from the first conductive pattern and the second conductive pattern.

13. The semiconductor package of claim 12, wherein a width of the first conductive pattern is different from a width of the second conductive pattern.

14. The semiconductor package of claim 9, wherein the silicon oxide layer has a first thickness, and
wherein at least one of the first bonding layer or the second bonding layer has a second thickness greater than the first thickness.

15. The semiconductor package of claim 9, wherein the at least one pore is spaced apart from the first bonding layer and the second bonding layer.

16. A semiconductor package comprising:
a first semiconductor die including a first substrate, a first bonding layer on the first substrate, and a first conductive pattern passing through the first bonding layer;
a second semiconductor die disposed on the first semiconductor die and partially exposing an upper surface of the first semiconductor die, the second semiconductor die including a second substrate, a second bonding layer under the second substrate, and a second conductive pattern extending through the second bonding layer;
a silicon oxide layer interposed between the first bonding layer and the second bonding layer, the silicon oxide layer being in contact with a plurality of side surfaces of the first conductive pattern and the second conductive pattern;
a mold layer covering a side surface of the second semiconductor die and an upper surface of the first semiconductor die; and
an external connection terminal bonded to a lower surface of the first semiconductor die,
wherein the first bonding layer and the second bonding layer comprise silicon carbon nitride (SiCN),
wherein the first bonding layer or the second bonding layer has a first thickness,
wherein the silicon oxide layer has a second thickness smaller than the first thickness,
wherein at least one pore is disposed in the silicon oxide layer, and
wherein the at least one pore is spaced apart from the first conductive pattern and the second conductive pattern.

17. The semiconductor package of claim 16, wherein the at least one pore has a height of 1 Å to 2 nm.

18. The semiconductor package of claim 16, wherein the at least one pore has a width of 1 nm to 100 nm.

19. The semiconductor package of claim 16, wherein a width of the first conductive pattern is different from a width of the second conductive pattern.

20. The semiconductor package of claim 16, wherein the at least one pore is spaced apart from the first bonding layer or the second bonding layer.

21-30. (canceled)
